(19) United States
(12) Patent Application Publication
(10) Pub. No.: US 2013/0186336 A1
(43) Pub. Date: Jul. 25, 2013

(54) DEVICE FOR PLASMA TREATMENT OF WORKPIECES

(71) Applicants: Sönke Siebels, Hamburg (DE); Hartwig Müller, Lutjensee (DE)

(72) Inventors: Sönke Siebels, Hamburg (DE); Hartwig Müller, Lutjensee (DE)

(73) Assignee: KHS CORPOPLAST GMBH, Hamburg (DE)

(21) Appl. No.: 13/702,662

(22) PCT Filed: Jun. 3, 2011
(86) PCT No.: PCT/DE2011/001158

§ 371 Date: Mar. 14, 2013

(30) Foreign Application Priority Data
Jun. 7, 2010 (DE) 10 2010 023 119.3

(51) Int. Cl. C23C 16/458

(52) U.S. Cl. CPC C23C 16/458
USPC 118/723 MW; 118/723 R

(57) ABSTRACT

A device for plasma treatment of workpieces. The workpiece is placed into a chamber of a processing station that can be at least partially evacuated. The plasma chamber is bounded by a chamber floor, a chamber cover, and a side chamber wall. The plasma chamber is coupled to a device for feeding and/or discharging process gases in a controlled manner. The plasma chamber is further disposed on a rotatable plasma wheel supported on a static base. At least one process gas channel is disposed in the region of the base, bounded at least in regions by a cover. The cover is implemented as part of the plasma wheel and includes at least one connection opening to the process gas channel. The connection opening can be coupled to an inner chamber by a connecting channel and at least one control valve.

The invention relates to a device for plasma treatment of workpieces, wherein the device includes at least one evacuatable plasma chamber for receiving the workpieces, wherein the plasma chamber is arranged in the area of a treatment station, and wherein the plasma chamber is defined by a chamber floor, a chamber cover, as well as a lateral chamber wall, and wherein the plasma chamber is provided with a device for the controllable supply and/or discharge of process gasses.

Such methods and devices are used, for example, for providing synthetic materials with surface coatings. In particular, such devices are known already in this connection for coating the inner or outer surfaces of containers which are intended for packaging liquids. In addition, devices for plasma sterilization are already known.

POT-WO 95/22413 describes a plasma chamber for internal coating of bottles of PET. The bottles to be coated are pushed through a moveable floor into a plasma chamber and are connected to an adapter in the area of a bottle opening. An evacuation of the bottle interior can then be carried out through the adapter. Moreover, a hollow gas lance is introduced into the interior of the bottles in order to supply process gas. An ignition of the plasma takes place with the use of a microwave.

It is also already known from this publication to arrange a plurality of plasma chambers on a rotating wheel. As a result, a high production rate of bottles per unit of time is reinforced.

In EP-OS 10 10 773, a supply device is explained for evacuating a bottle interior and supplying it with process gas. PCT-WO 01/31680 describes a plasma chamber into which the bottles are inserted by means of a movable cover which has been previously connected with an opening area of the bottles.

PCT/WO 00/58631 also shows already the arrangement of plasma stations on a rotating wheel and describes for such an arrangement an assignment by groups of negative pressure pumps and plasma stations for reinforcing a favorable evacuation of the chambers and of the interior spaces of the bottles. Moreover, the coating of several containers in a common plasma station or a common cavity is mentioned.

Another arrangement for carrying out an internal coating of bottles is described in PCT-WO 99/17334. In particular, an arrangement of a microwave generator above the plasma chamber, as well as a vacuum and operating medium supply through a floor of the plasma chamber, is described.

In DE 10 2004 020 185 A1, a gas lance is already described which can be inserted into the interior space of a preform to be coated and which serves for supplying process gas. The gas lance can be positioned in the longitudinal direction of the container.

In the predominant number of known devices, container layers of silicon oxides having the general chemical formula SiOₓ produced by the plasma are used for improving the barrier properties of the thermoplastic synthetic material. Such barrier layers prevent a penetration of oxygen into the packaged liquids as well as a discharge of carbon dioxide in the case of CO₂ containing liquids.

The plasma stations are typically connected to negative pressure sources providing different negative pressures; moreover, it is necessary to supply different process gasses for carrying out the plasma treatment. The control of this supply and the discharge of process gasses take place typically with the use of control valves which are connected on the output side to the plasma chamber and on the input side through connecting lines to the respectively assigned process gas sources. The respective connection to the process gas sources is of relatively complicated construction if the plasma chambers are arranged together with the valves on a rotatable plasma wheel. In that case, the valves are initially connected through lines to a rotary distributor which, in turn, is connected through additional connecting lines to the stationary process gas sources.

The connection technology described above results in a plurality of couplings and connecting elements, which may lose their tightness over longer periods of operation. With respect to the connection of the plasma chambers to the negative pressure sources, relatively large cross sections of the lines become necessary for preventing flow losses.

It is the object of the present invention to construct a device of the above described type in such a way that an effective process gas supply of the plasma chambers is reinforced.

In accordance with the invention, this object is met by arranging the plasma chamber on a rotatable plasma wheel which is mounted on a stationary base, and by arranging in the area of the base at least one process gas duct which is defined over at least portions thereof by a cover which is formed as part of the plasma wheel, wherein the cover has at least one connection opening to the process gas duct which can be coupled through a connecting duct and at least one control valve to an interior space of the plasma chamber.

The stationary arrangement of the process gas duct in the area of the base and the arrangement of the control valve in the area of the cover rotating together with the plasma wheel, facilitate an extremely compact construction. The process gas duct may extend in close immediate spatial vicinity of the plasma chamber and may be provided with a large cross section. As a result, the supply of the plasma chamber takes place with a small flow resistance. Moreover, the number of structural elements which must be connected, as compared to the prior art, is significantly reduced and the danger of leakage is reduced. Moreover, with respect to the running operation, the necessary service and maintenance operations are minimized.

The device according to the invention is particularly suitable for supporting the sequence of a coating process for bottles of synthetic material. In this case, particularly an inner coating of these bottles with a layer of SiOₓ, wherein the adherence of the layer of SiOₓ on the synthetic material can be improved by means of an intermediate layer, which is constructed as an adhesion promoter. The coating method is carried out preferably as a PICVD plasma process (plasma impulse induced chemical vapor deposition). In such a method the plasma is ignited with the use of impulses of a microwave. The impulses may be controlled with respect to their impulse width, the impulse spacing, as well as the impulse height.

The seal between the cover and the walls of the process gas duct is simplified by the fact that the process duct extends essentially concentrically to an axis of rotation of the plasma wheel.

A compact construction is supported by arranging the control valve in the area of a valve block.

Also, the compactness of the arrangement is reinforced by the fact that at least one duct connecting the control valve to the plasma station extends within the valve block.

A simultaneous supply of a plurality of cavities is achieved by the fact that the duct has at least one duct branch for connecting the control valve to at least two cavities.

The supply and discharge of workpieces to be treated is facilitated by the fact that the cavities are arranged essentially extending in a row along a circumference of the plasma wheel.

An essentially exclusively horizontally extending transport path of the workpieces can be achieved by arranging a chamber wall of the plasma station so as to be positionable in a vertical direction.

A long operating capability of the microwave generators is reinforced by immovably arranging a microwave generator relative to a station frame of the plasma station.

A compact construction of the plasma wheel and a good accessibility is reinforced by arranging the plasma duct inwardly relative to the plasma station on the plasma wheel.

In addition, for a compact construction as well as a good accessibility, the process gas duct has an essentially rectangular cross sectional surface and is limited upwardly in the vertical direction by the cover.

In the drawings, embodiments of the invention are schematically illustrated. In the drawing:

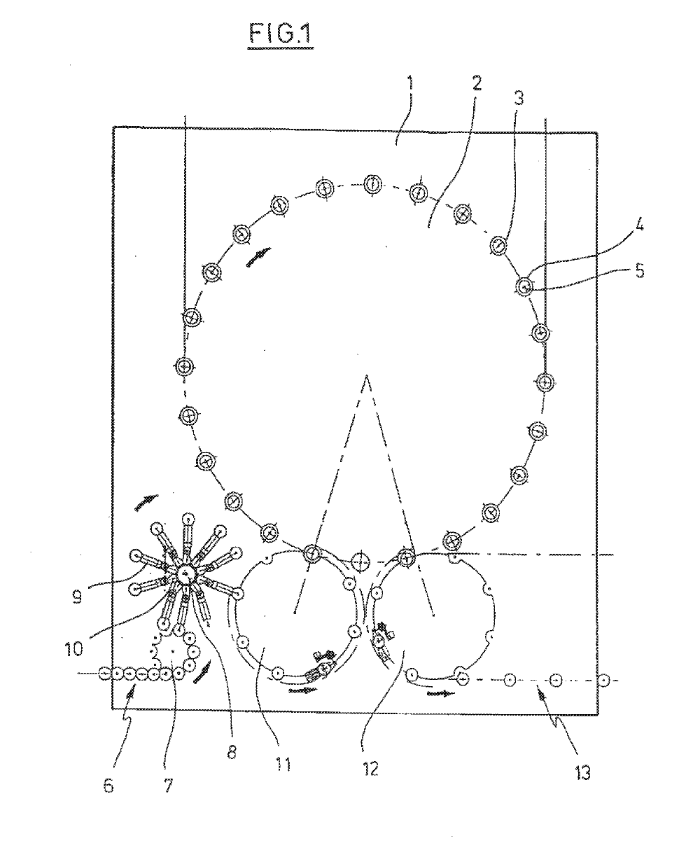

FIG. 1 is a sketch showing the principle of a plurality of plasma chambers which are arranged on a rotating plasma wheel and in which the plasma wheel is coupled to input and output wheels,

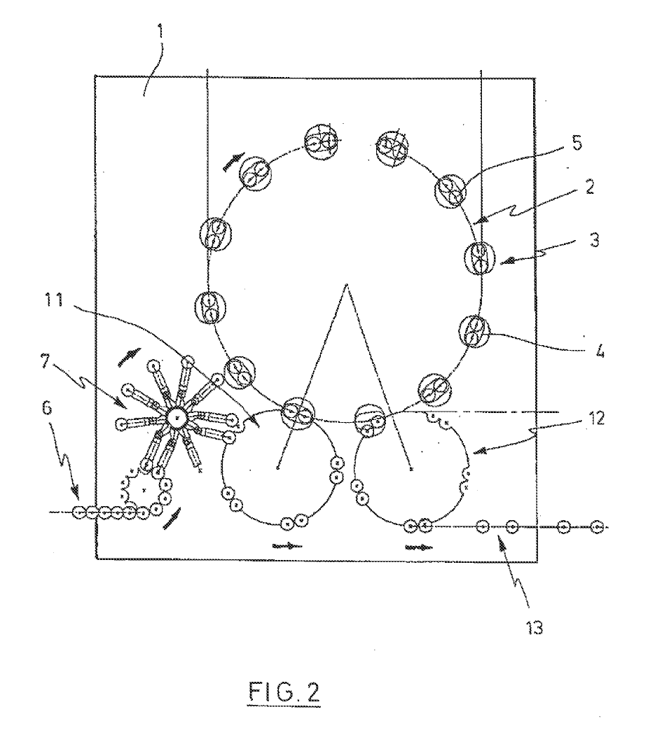

FIG. 2 shows an arrangement, similar to FIG. 1, in which the plasma stations are each equipped with two plasma chambers,

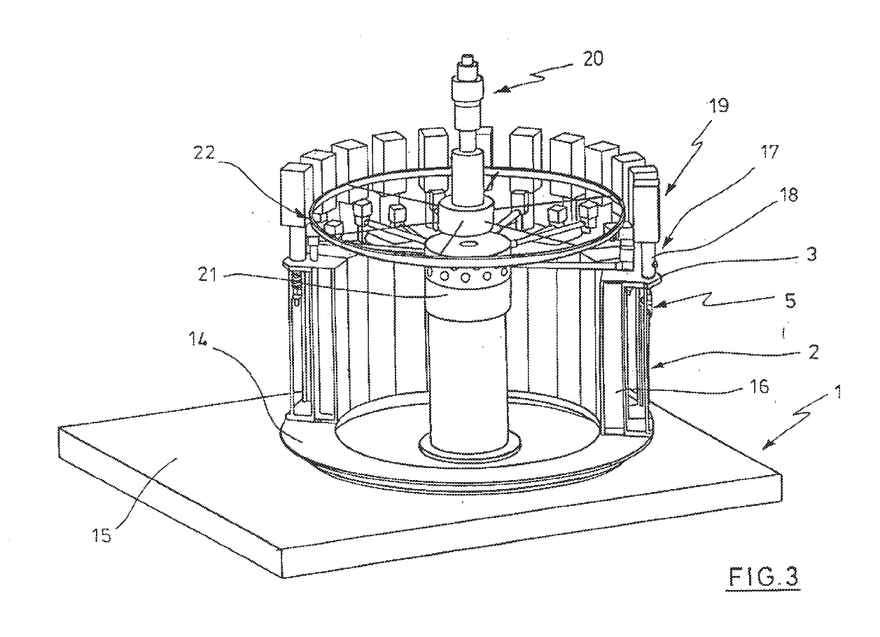

FIG. 3 shows a perspective illustration of a plasma wheel with a plurality of plasma chambers,

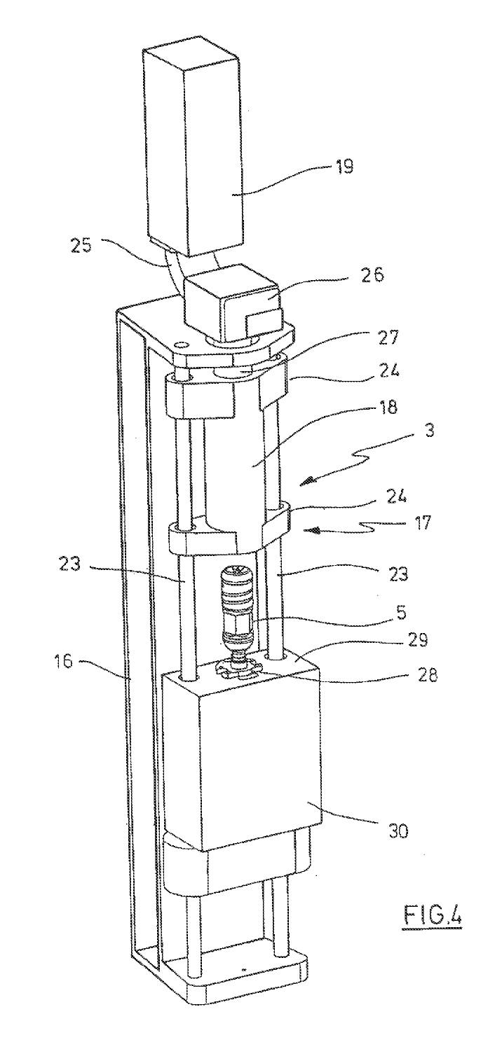

FIG. 4 shows a perspective illustration of a plasma station with a cavity,

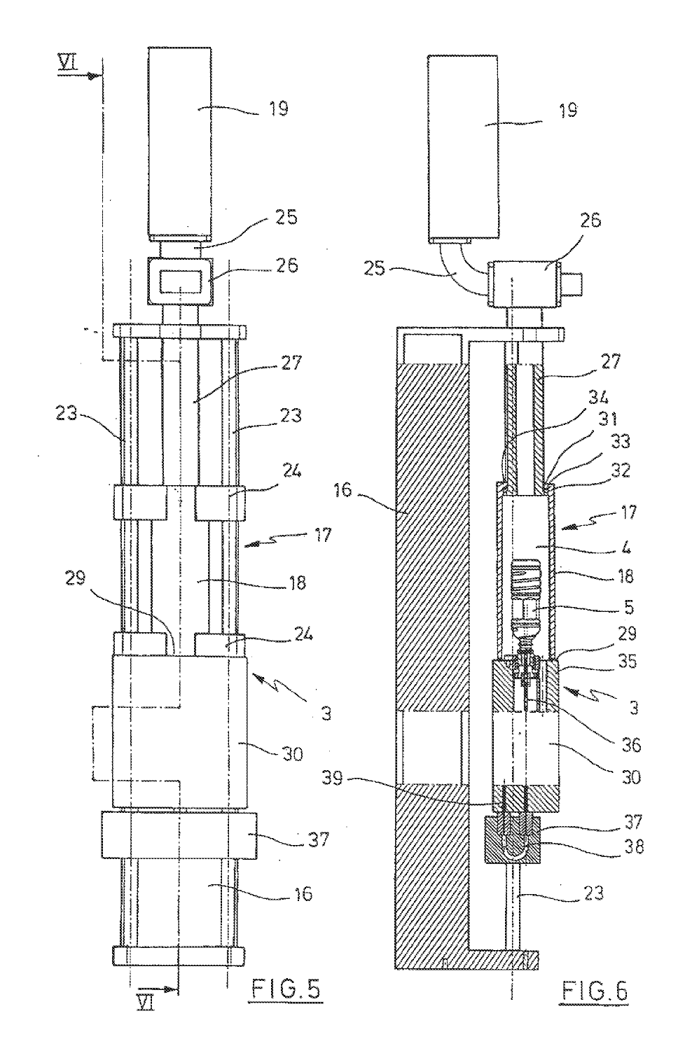

FIG. 5 is a front view of the device according to FIG. 4 with an enclosed plasma chamber,

FIG. 6 shows a cross sectional view according to sectional line VI-VI in FIG. 5,

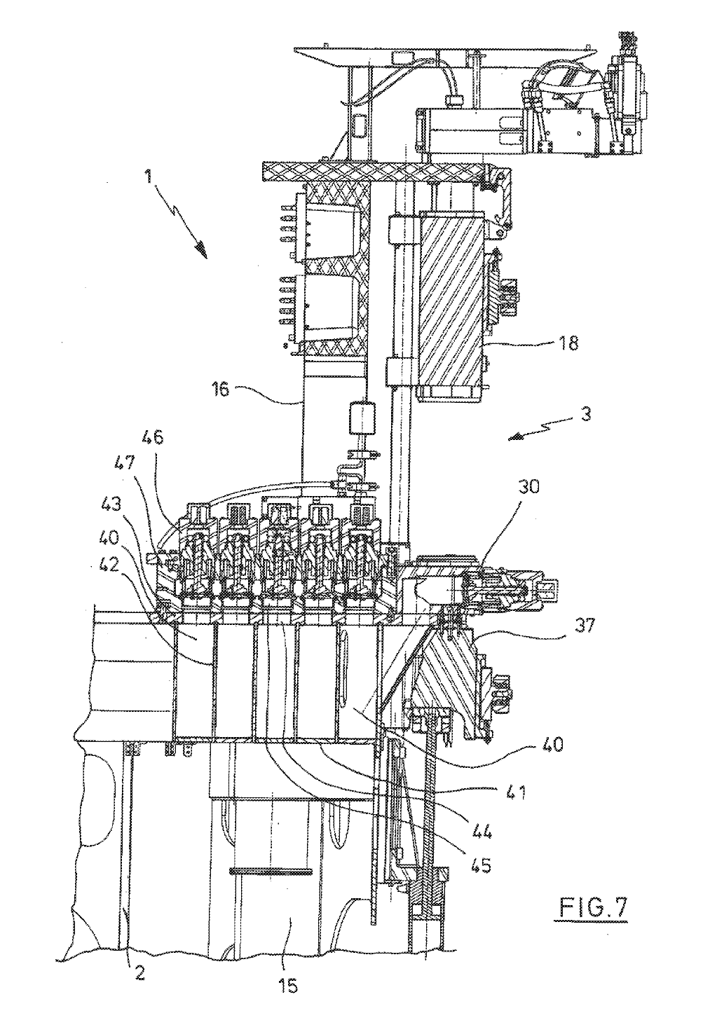

FIG. 7 is a partial illustration of a vertical sectional view through the stationary base and the processing station for illustrating the spatial relationship of the process gas ducts and the control valves,

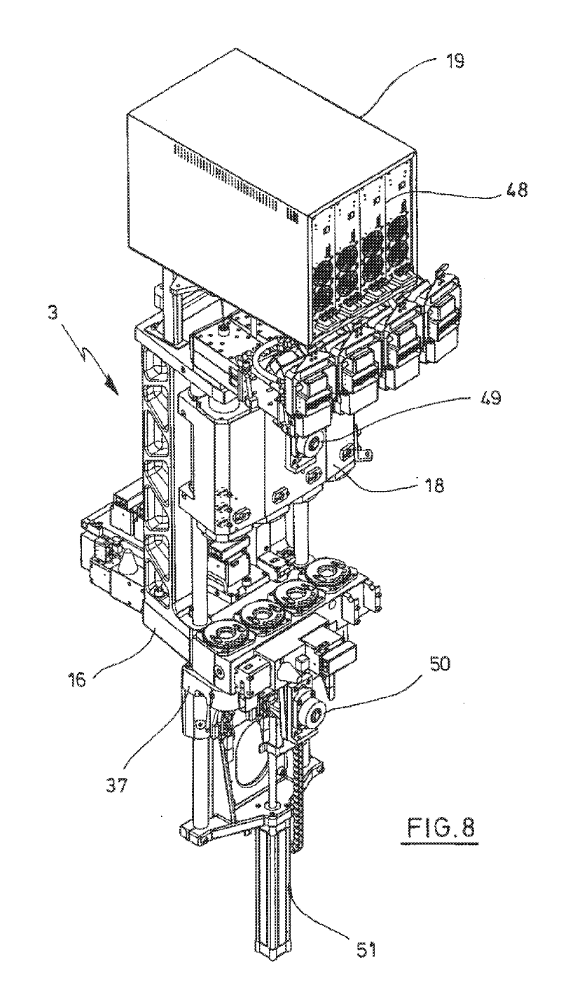

FIG. 8 is a perspective illustration of a plasma station with four cavities, and

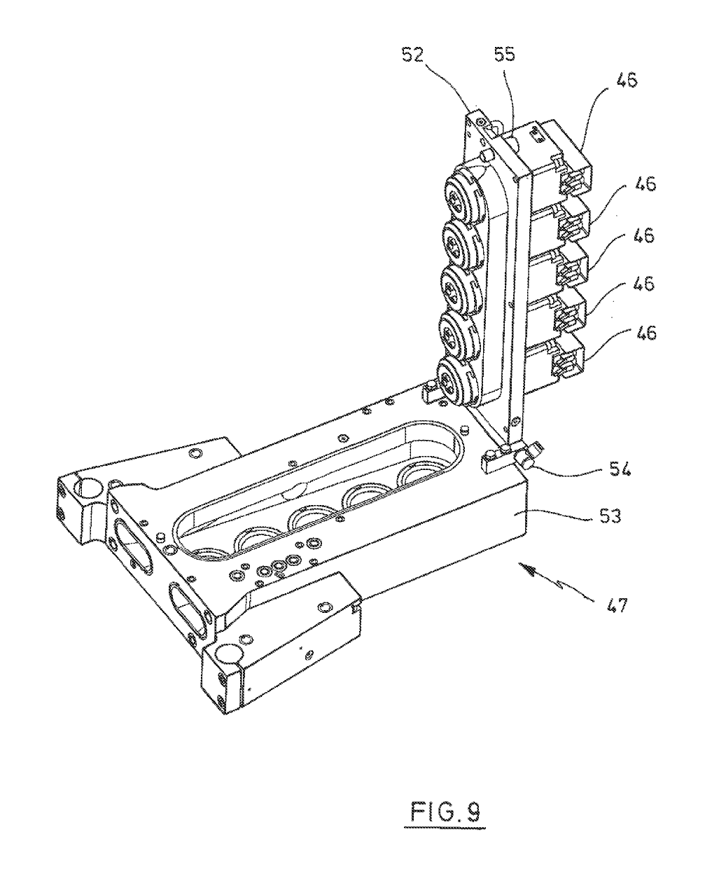

FIG. 9 is a perspective illustration of a plate-like valve support that is folded up for cleaning purposes.

From the illustration in FIG. 1, it can be seen that a plasma module 1 is provided with a rotating plasma wheel 2. Along a circumference of the plasma wheel 2, a plurality of plasma stations 3 are arranged. The plasma stations 3 are provided with cavities 4 or plasma chambers 17 for receiving workpieces 5 to be treated.

The workpieces 5 to be treated are supplied to the plasma module 1 in the area of an input 6 and are conducted further through a singling wheel 7 to a transfer wheel 8 which is equipped with positionable support arms 9. The support arms 9 are arranged so as to be pivotable relative to a base 10 of the transfer wheel 8, so that a change of the distance of the workpieces 5 relative to each other can be carried out. As a result, the workpieces 5 are transferred relative to the singling wheel 7 by the transfer wheel 8 to an input wheel 11 with an increased distance of the workpieces 5 relative to each other. The input wheel 11 transfers the workpieces 5 to be treated to the plasma wheel 2. After carrying out the treatment, the treated workpieces 5 are removed by an output wheel 12 from the area of the plasma wheel 2 and into the area of an output section 13.

In the embodiment in accordance with FIG. 2, the plasma stations 3 are each equipped with two cavities 4 or plasma chambers 17. This makes it possible to treat always two workpieces 5 simultaneously. It is basically possible in this connection to construct the cavities 4 completely separate from each other. However, it is basically also possible to define only partial areas in such a way relative to each other in a common cavity space in such a way that an optimum coating of all workpieces 5 is ensured. In particular, it is contemplated in this connection to delimit the partial cavities, at least by separate microwave couplings, relative to each other.

FIG. 3 shows a perspective illustration of a plasma module 1 with partially built-up plasma wheel 2. The plasma stations 3 are arranged on a support ring 14 which is constructed as a part of a rotary connection and are arranged in the area of a machine base 15. The plasma stations 3 each have a station frame 16 which supports plasma chambers 17. The plasma chambers 17 include cylindrically shaped chamber walls 18 as well as microwave generators 19.

The plasma stations 3 are supplied with energy by means of a rotary distributor 20 arranged in a center of the plasma wheel 2. In particular ring lines 21 can be used for the distribution of the operating materials.

The workpieces 5 to be treated are illustrated underneath the cylindrically shaped chamber walls 18. Bottom portions of the plasma chambers 17 are not illustrated for simplicity's sake.

FIG. 4 shows a plasma station 3 in a perspective illustration. It can be seen that the station frame 16 is provided with guide rods 23 on which a carriage 24 is guided for supporting the cylindrically shaped chamber wall 18. FIG. 4 shows the carriage 24 with chamber wall 18 in a raised position so that the workpiece 5 is released.

The microwave generator 19 is arranged in the upper area of the plasma station 3. The microwave generator 19 is connected through a deflection 25 and an adapter 26 to a coupling duct 27 which opens into the plasma chamber 17. The microwave generator 19 can basically be coupled to the chamber cover 31 either directly in the area of the chamber cover 31, as well as through a spacer element to a predeterminable distance to the chamber cover 31 and, thus, is arranged in a larger ambient area of the chamber cover 31. The adapter 26 has the function of a transfer element, and the coupling duct 27 is constructed as a coaxial conductor. A quartz glass window is arranged in the area of an opening of the coupling duct 27 into the chamber cover 31. The deflection 25 is constructed as a hollow conductor.

The workpiece 5 is positioned by a support element 28 which is arranged in the area of a chamber floor 29. The chamber floor 29 is constructed as a portion of a chamber base 30. For facilitating an adjustment, it is possible to fix the chamber base 30 in the area of the guide rods 23. In accordance with another variation, the chamber base 30 is fastened directly to the station frame 16. For example, in such an arrangement, it is also possible to construct the guide rods 23 in the vertical direction in two pieces.

FIG. 5 shows a front view of the plasma station 3 in accordance with FIG. 3 in a closed state of the plasma chamber 17. The carriage 24, together with the cylindrically shaped chamber wall 18, is in this case lowered relative to the positioning in FIG. 4, so that the chamber wall 18 is moved against the chamber floor 29. In this positioning state, the plasma coating can be guided through.

FIG. 6 shows in a vertical sectional view the arrangement according to FIG. 5. It can be seen especially that the coupling duct 27 opens into a chamber cover 31 which has a laterally protruding flange 32. In the area of the flange 32, a seal 33 is arranged which is acted upon by an internal flange 34 of the chamber wall 18. Consequently, in a lowered state of the chamber wall 18, the chamber wall 18 is sealed relative to the chamber cover 31. Another seal 35 is arranged in a lower portion of the chamber wall 18 in order to also ensure, in this case, that the chamber wall is sealed relative to the chamber floor 29.

In the position shown in FIG. 6 the chamber wall 18 encloses the cavity 4, so that an inner space of the cavity 4, as well as an inner space of the workpiece 5, can be evacuated. For reinforcing a supply of process gas, a hollow gas lance 36 is arranged in the area of the chamber base 30, which can be moved into the interior of the workpiece 5. For carrying out a positioning of the gas lance 36, the gas lance is supported by a lance carriage 37 which can be positioned along the guide rods 23. A process gas duct 38 extends within the lance carriage 37, wherein, in the raised position illustrated in FIG. 6, the process gas duct is coupled to a gas connection 39 of the chamber base 30. Because of this arrangement, hose-like connections on the lance carriage 37 are avoided.

In an alternative to the above explained construction, it is however also possible according to the invention to introduce the workpiece 5 into a plasma chamber 17 which is immovable relative to the assigned support structure. It is also possible, as an alternative to the illustrated coating of the workpieces 5 with their openings facing downwardly in the vertical direction, to carry out a coating of the workpieces with their openings facing upwardly in the vertical direction. In particular, it is contemplated to carry out a coating of bottle-shaped workpieces 5. Such bottles are preferably also made of a thermoplastic material. The use of PET or PP is preferably contemplated. In accordance with another preferred embodiment, the coated bottles serve for receiving beverages.

A typical treatment process is explained in the following in connection with an example of a coating procedure, and is carried out in such a way that, initially the workpiece 5 is transported to the plasma wheel 2 by using the input wheel 11, and that the placement of the workpiece 5 into the plasma station 3 is carried out in an upwardly pushed state of the sleeve-like chamber wall 18.

After the conclusion of the insertion procedure, the chamber wall 18 is lowered into its sealed position and, offset with respect to time, a displacement of the support element 28 follows, so that the interior of the workpiece 5 is closed off from the interior of the cavity 4. Subsequently, the gas lance 36 is moved into the interior of the workpiece. Also, it is possible to move the gas lance 36 already synchronously with the beginning lowering of the cavity 4 into the interior of the workpiece 5. This is followed, simultaneously or offset with respect to time, by an evacuation of the cavity 4 and of the interior of the workpiece 5. After a sufficient evacuation of the interior of the cavity 4, the pressure in the interior of the workpiece 5 is reduced subsequently even further. Moreover, it is contemplated to position the gas lance 36 at least already partially parallel to the positioning of the chamber wall 18.

After a sufficiently low negative pressure has been reached, process gas is conducted into the interior of the workpiece 5 and the plasma is ignited with the aid of the microwave generator 19. It is particularly contemplated to separate, by means of the plasma, an adhesion promoter on an inner surface of the workpiece 5 as well as the actual barrier layer of silicon oxides.

After completion of the coating process, the plasma chamber 17 and the interior of the workpiece 5 are vented. After reaching atmospheric pressure in the cavity 4 and the interior of the workpiece 5, the chamber wall 18 is lifted again and the gas lance 36 is again removed from the interior of the workpiece 5. A removal of the coated workpiece 54 and the introduction of a new workpiece 5 to be coated can now be carried out.

Positioning of the chamber wall 18 of the sealing element 28 and/or the gas lance 36 can take place with the use of different drive units. Basically, the use of pneumatic drives and/or electrical drives, particularly in an embodiment as linear motor, is conceivable. However, in particular, it is contemplated to realize a cam control for reinforcing axial movement coordination with a rotation of the plasma wheel 2. The cam control may be constructed, for example, in such a way that control cams are arranged along a circumference of the plasma wheel 2 along which the cam rollers are guided. The cam rollers are coupled to the respective structural elements to be positioned.

FIG. 7 illustrates the number of a plurality of process gas ducts 40 in the area of the machine base 15. The process gas ducts 40 each have a bottom 41 and side walls 42 which are fixedly connected to the machine base 15. Arranged opposite the floor 41 is a cover 43 which is constructed as a part of the plasma wheel 2. The cover 43 is guided so as to be sealed relative to the side walls 42.

In the area of the cover 43, connecting openings 44 are arranged which open into the process gas ducts 40. The connecting openings 44 are each coupled to control valves 46 through connecting ducts 45.

The control valves 46 control a connection of the plasma stations 3 with the process gas ducts 40 and, thus, also with the assigned process gas supplies. In particular it is contemplated to arrange the control valves 46 in the area of a valve block 47 which, in turn, is connected to the chamber base 30.

In an arrangement of several cavities 4 in the area of the plasma station 3, duct branches are arranged in the area of the valve block 47 in order to be able to supply a certain process gas through only one control valve 46 of the plurality to cavities 4, or to be able to realize a connection to the negative pressure supply.

Typically, the process gas ducts 40 extend concentrically to a center point of the plasma wheel 2. In the illustrated embodiment, the process gas ducts 40 are open toward the top and are provided in the area of the upper extension with the cover 43. However, any other spatial orientation of the process gas ducts 40 is basically conceivable, for example, with the cover 43 underneath the process gas ducts or next to the process gas ducts.

FIG. 8 shows a plasma station 3 with four cavities 4. The microwave generator 19 typically has a number of microwave modules 48 which correspond to the number of cavities 4. As a result, a separate microwave module 48 can be assigned to each of the cavities 4.

In accordance with a preferred embodiment, positioning of the chamber wall 18 takes place mechanically with the use of a cam control. In that case, a cam roller 49 connected to the chamber wall 18 is guided along a corresponding cam track.

For positioning the lance carriage 37, preferably a mechanical cam control is also used. The lance carriage 37 is for this purpose provided with a cam roller 50.

Positioning of the gas lances 36, not illustrated in FIG. 8, relative to the lance carriage 37, takes place preferably with the use of a pneumatic cylinder 51. By combining the mechanical control as well as the pneumatic control, the processes of sealing the cavities 4 and the workpieces 5, and the actual movement of the gas lances 36 into the workpieces 5, can be operatively uncoupled.

FIG. 9 shows a perspective illustration of the valve block 47. It can be seen that a support plate 52, which supports the control valves 46, is arranged so as to be pivotable relative to a base element 53. A pivoting joint 54 is used for this purpose. The pivoting joint 54 is preferably arranged on a side of the base element 53 which is located on the inside in a radial direction of plasma wheel 2. The upwardly folded state of operation illustrated in FIG. 9 causes the bottom sides of the control valves 56 and valve seats arranged in the area of the base element 53 to be easily accessible and to be capable of being cleaned.

After pivoting the support plate 52 back into a closed position, the support plate 52 is locked relative to the base element 53 by a fixing element 55. The fixing element 55 may be constructed as a screw.

An arrangement of the individual process gas duct 40 in a radial direction of the plasma wheel 2 is effected preferably in dependence on the respectively effective flow-technological conductance. This is understood to be the quotient of volumetric flow and pressure. The higher this conductance, the more critical the vacuum-technical requirements become. This means that higher requirements are made with increasing volumetric flow or decreasing pressures.

The process gas duct 40 with the relatively pressure is arranged radially inwardly and, thus, the farthest from the plasma station 3. This is where the lowest vacuum-technical conductance is present. This is followed outwardly in the radial direction of the plasma wheel 2 and, thus, at the shortest distance from the plasma station 3 by the process gas supplies having increasing conductances to be considered.

1-10. (canceled)

11. A device for plasma treatment of workpieces, comprising: at least one evacuatable plasma chamber for receiving the workpieces, wherein the plasma chamber is part of a plasma station and is arranged in the area of a treatment station, wherein the plasma chamber is defined by a chamber floor, a chamber cover, and a lateral chamber wall; a device coupled to the plasma chamber for the controllable supply and/or discharge of process gasses; a stationary base; a rotatable plasma wheel supported on the stationary base, the plasma chamber being arranged on the rotatable plasma wheel; at least one process gas duct is arranged in an area of the base, wherein the plasma wheel includes a cover that bounds the process gas duct at least over portions thereof and wherein the cover has at least one connecting opening to the process gas duct; and a connecting duct and at least one control valve for coupling the connecting opening of the cover to an interior space of the plasma chamber.

12. The device according to claim 11, wherein the process gas duct extends substantially concentrically to an axis of rotation of the plasma wheel.

13. The device according to claim 11, further comprising a valve block, the control valve being arranged in an area of the valve block.

14. The device according to claim 13, wherein at least one duct is arranged in the valve block so as to connect the control valve with the plasma station.

15. The device according to claim 14, wherein the duct has at least one duct branch that connects the control valve to at least two chambers.

16. The device according to claim 11, wherein the chambers are arranged in a row along a circumference of the plasma wheel.

17. The device according to claim 11, wherein a chamber wall of the plasma station is arranged so as to be positionable in a vertical direction.

18. The device according to claim 11, further comprising a microwave generator arranged so as to be immovable relative to a station frame of the plasma station.

19. The device according to claim 11, wherein the process gas duct is arranged inwardly on the plasma wheel relative to the plasma station.

20. The device according to claim 11, wherein the process gas duct has a substantially rectangular cross sectional area and is upwardly bounded in a vertical direction by the cover.
